(19) United States
(12) Patent Application Publication
(10) Pub. No.: US 2012/0322170 A1
(43) Pub. Date: Dec. 20, 2012

(54) PINHOLE INSPECTION METHOD OF INSULATOR LAYER

(75) Inventors: Po-Fu CHOU, Taoyuan City (TW); Chun-Ming Tsai, Hsinchu City (TW)

(73) Assignee: UNITED MICROELECTRONICS CORP., HSINCHU (TW)

(21) Appl. No.: 13/159,763

(22) Filed: Jun. 14, 2011

(51) Int. Cl. H01L 21/66

(52) U.S. Cl. 438/9; 257/E21.528

(57) ABSTRACT

A pinhole inspection method of an insulator layer, wherein the pinhole inspection method comprises steps as following: A dry etching process is firstly performed to remove a contiguous layer adjacent to the insulator layer. Subsequently an etching endpoint is determined and the dry etching process is then stopped in accordance with a second electron energy variation triggered by the dry etching process. Afterward, a cross-sectional morphology or topography of the insulator layer is inspected.

### FIELD OF THE INVENTION

The present invention relates to a fault detecting method of a semiconductor device, more particularly to a method for detecting and inspecting pinholes formed in an insulator layer of a semiconductor device.

### BACKGROUND OF THE INVENTION

In semiconductor device fabrication, engineers routinely analyze defective device to discover the cause of defect, thereby hoping to prevent future ones. This process is commonly referred to as “Failure analysis”. A pinhole inspection of an insulator layer, for example a pinhole inspection of a gate oxide layer, is a commonly used “Failure analysis” for detecting defects existing in the gate oxide layer and discovering the cause of defect. Consequently, the fabrication process of the gate oxide layer can be improved in accordance with the inspecting results to prevent the defects from being reproduced.

Traditionally, to inspect the pinholes existing in gate oxide layer of a transistor, a delayer process may be performed on the front side of the transistor under inspection to remove various upper layers, such as the passivation layers, the metal layers, the inter layer dielectric (ILD) layers, covering the transistor to expose the poly silicon of the transistor; and afterward the poly silicon may be subsequently removed by an etching processes, so as to expose the gate oxide layer for the subsequent inspection. However, because to control the etching process just stopping on the gate oxide layer is very difficult, the gate oxide layer may be over etched and the etching reagent may diffuse downwards to the silicon substrate via the pinholes formed in the gate oxide layer, thereby the morphology of the pinholes may be deformed and the subsequent pinhole morphology inspection may be obstructed. Besides, when a high-k metal gate with various material layers is adapted, it requires different etching reagents to remove the high-k metal gate and make the front side inspection getting more complicated. These problems may get worse as the feature size of the semiconductor device shrinks.

To solve these problems a backside inspection was adopted, by which the transistor is flip over, and the silicon substrate is then removed to expose the gate oxide layer for the subsequent inspection. However the over etch problems and the etching endpoint control issues may still exist. Therefore, it is necessary to provide an improved method for detecting and inspecting insulator pinholes formed in a semiconductor device to obviate the drawbacks and problems encountered from the prior art.

### SUMMARY OF THE INVENTION

One aspect of the present invention is to provide a method for inspecting pinholes formed in an insulator layer of a semiconductor device, wherein the pinhole inspection method comprises steps as the following: A dry etching process is firstly performed to remove a contiguous layer adjacent to the insulator layer. Subsequently an etching endpoint is determined in accordance with a second electron energy variation triggered by the dry etching process to stop the dry etching process. Afterward, a cross-sectional morphology or topography of the insulator layer is inspected.

In one embodiment of the present invention, the dry etching process is a focus ion beam (FIB) milling process. Preferably, a thin layer of the contiguous layer is remained after the dry etching process is carried out. In one embodiment of the present invention, the insulator layer is a silicon oxide layer and preferably, the contiguous layer is a silicon substrate for forming the semiconductor device.

In one embodiment of the present invention, prior to performing the dry etching process, a pre-thinning process is carried out to remove a portion of the substrate.

In another embodiment of the present invention, the determination of the etching endpoint comprises steps of grounding the insulator layer, whereby the etching endpoint can be determined while the second electron energy is significantly increased. In another embodiment of the present invention, the determination of the etching endpoint comprises steps of imposing a voltage to the contiguous layer which is subjected to the dry etching process, whereby the etching endpoint can be determined while the second electron energy steeply varies.

In another embodiment of the present invention, the cross-sectional morphology or topography of the insulator layer is inspected by utilizing electron microscopes such as a transmission electron microscope (TEM), a scanning electron microscope (SEM), a Focus ion beam (FIB) or an optical microscope.

Another aspect of the present invention is to provide a method for inspecting pinholes formed in a gate oxide layer of a semiconductor device, wherein the pinhole inspection method comprises steps as the following: A dry etching process is firstly performed to remove a contiguous layer adjacent to the gate oxide layer. Subsequently an etching endpoint is determined in accordance with a second electron energy variation triggered by the dry etching process to stop the dry etching process. Afterward, a cross-sectional morphology or topography of the gate oxide layer is inspected.

In one embodiment of the present invention, the dry etching process is a FIB milling process. Preferably, a thin layer of the contiguous layer is remained after the dry etching process is completed.

In one embodiment of the present invention, the semiconductor is a transistor and the contiguous layer is a silicon substrate for forming the transistor. In one embodiment of the present invention, the transistor has a high-k metal gate. In one embodiment of the present invention, prior to performing the dry etching process, a pre-thinning process is carried out to remove a portion of the substrate.

In another embodiment of the present invention, the determination of the etching endpoint comprises steps of grounding the gate oxide layer, whereby the etching endpoint can be determined while the second electron energy is significantly increased. In another embodiment of the present invention, the determination of the etching endpoint comprises steps of imposing a voltage to the contiguous layer which is subjected to the dry etching process, whereby the etching endpoint can be determined while the second electron energy steeply varies.

In another embodiment of the present invention, the cross-sectional morphology or the topography of the insulator layer is inspected by utilizing a TEM, a SEM, a FIB or an optical microscope.

In accordance with the aforementioned embodiments of the present invention, a method for inspecting pinholes formed in an insulator layer of a semiconductor device is provided, an etching process is firstly performed to remove the contiguous layer adjacent to the insulator layer under inspection; an etching endpoint is then determined by a second electron energy variation triggered by the dry etching process; after the etching process is stopped, the cross-sectional morphology or topography of the insulator is inspected. Since the dry etching process can be precisely stopped in accordance with the second electron energy variation before the insulator is damaged, such that the pinholes existing in the insulator layer can be maintained without deformation and the “Failure analysis” can be performed more easily and efficiently. Therefore, the drawbacks and problems encountered from the prior art can be solved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1C illustrate cross-sectional views of a transistor under a pinhole inspection process in accordance with one embodiment of the present invention.

FIG. 2 illustrates a schematic of a FIB tool used to conduct the dry etching process in accordance with one embodiment of the present invention.

FIG. 3 illustrates a cross-sectional view of a transistor under a pinhole inspection process in accordance with one embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed. For example, although the following detail descriptions of the present invention disclose several methods for inspecting pinholes formed in a gate oxide layer of a transistor, however, these approaches are not only applicable to a gate oxide layer of a transistor but also to other insulator layers of any semiconductor device for inspecting pinholes formed therein.

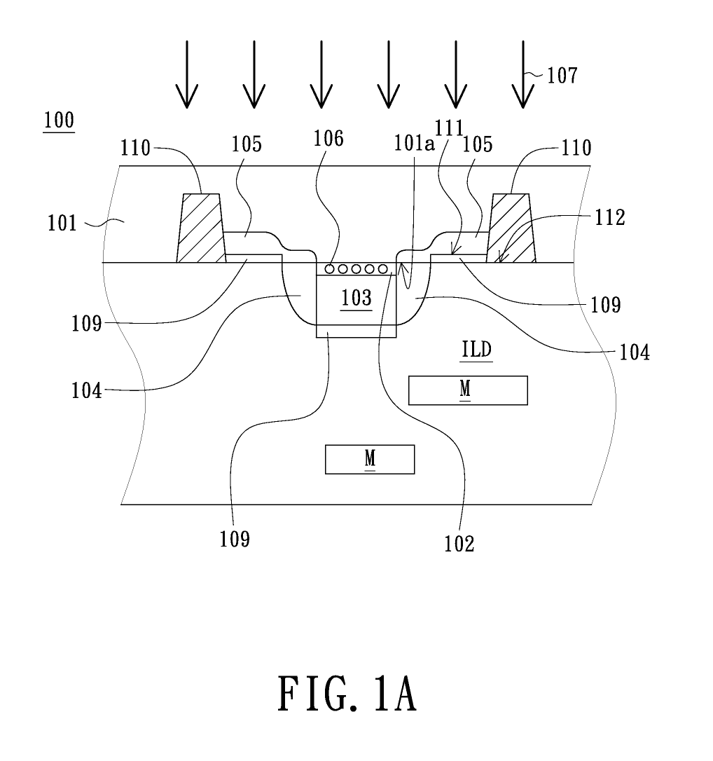

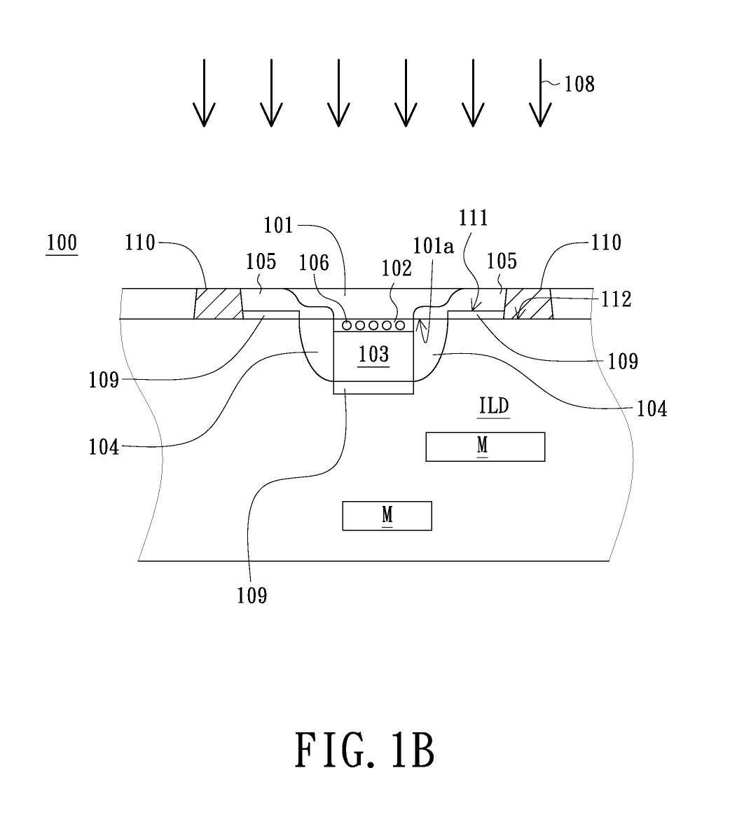

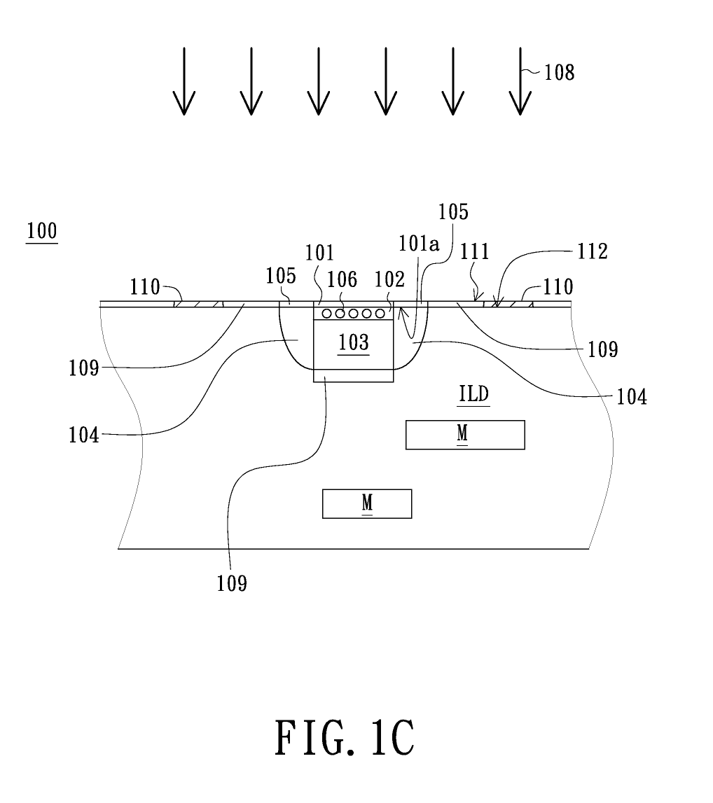

FIGS. 1A to 1C illustrate cross-sectional views of a transistor 100 under a pinhole inspection process in accordance with one embodiment of the present invention.

Referring to FIG. 1A, the transistor 100 is formed on an active area of a silicon substrate 101 which is defined by shallow trench isolators (STI) 110. The transistor 100 comprises a gate oxide layer 102, a poly gate 103, a spacer 104, source/drain regions 105 and a silicide layer 109. Wherein the gate oxide layer 102 is formed on the silicon substrate 101. The poly gate 103 is formed on the gat oxide layer 102. The spacer 104 is formed on the silicon substrate 101 and surrounding the poly gate 103 and the gate oxide 102. The source/drain regions 105 are formed in the silicon substrate 101 adjacent to the spacer 104. The silicide layer 109 is disposed on the poly gate 103 and the source/drain regions 105.

The pinhole inspection process is performed for inspecting the pinholes 106 formed in the gate oxide layer 102 of the transistor 100. This pinhole inspection process comprises steps as follows: Firstly, the transistor 100 is flipped over and a dry etching process 108 (shown in FIG. 1B) is performed on the silicon substrate 101 in order to remove a portion of the silicon substrate 101 beneath (or over) the transistor 100.

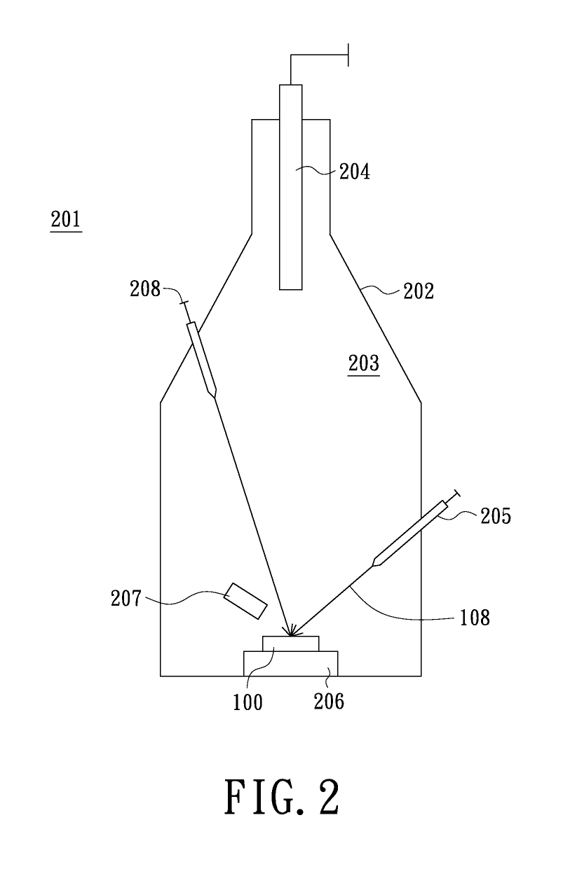

In some embodiments of the present invention, the dry etching process is a FIB milling process. FIG. 2 illustrates a schematic of a FIB tool 201 used to conduct the dry etching process 108 in accordance with one embodiment of the present invention. The FIB tool 201 includes an enclosure wall of a tool housing 202 that encloses a tool chamber 203. A SEM 204 extends through the housing wall 202 into the tool chamber 203 at an angle of tilt relative to a FIB tube 205 and a horizontal surface of a test specimen (i.e the transistor 100) mounted on a stage 206. A nozzle 204 of a gas injection system (GIS) 208 also extends through the housing wall 202 into the tool chamber 203, and is adapted to introduce a gas, such as gaseous XeF2, into contact with or in proximity to the transistor 100. A voltage is imposed to the transistor 100 via the stage 206 and a detector 207 is used to measure the secondary electrons energy generating from the transistor 100 subjected to the FIB milling (i.e. the dry etching process 108).

To improve the dry etch process 108 efficiency, in some embodiments of the present invention, a pre-thinning process 107, such as a grinding, chemical mechanical polishing (CMP) or other suitable process, is carried out to remove a majority portion of the silicon substrate 101 prior to the dry etching process 108 (see FIG. 1A), such that the etching end point of the subsequent FIB milling process can be obtained more quickly and the production lead-time and cost can also be saved.

Subsequently an etching endpoint is determined and the dry etching process 108 is then stopped in accordance with the second electron energy variation triggered by the dry etching process. Because different layers of the transistor 100 may generate different amount of secondary electrons, as being subjected to the FIB milling, thus the secondary electron energy measured by the detector 207 may steeply vary while the dry etching process 108 encounters the interface of two adjacent layers, whereby the dry etching process 108 can be precisely stopped on the interface of the two adjacent layers, if the etching endpoint is predetermined on the next layer. In other words, if the dry etching process 108 is predetermined to stop on the next layer, the etching endpoint can be easily determined by the FIB tool 201 illustrated in FIG. 2.

In the present invention, for the purpose for inspecting the cross-sectional morphology and the topography of the gate oxide layer 102, the etching endpoint of the dry etching process 108 is preferably stopped on the interface 111 of the silicon substrate 101 and silcide layer 109. Because the silicide layer 109 disposed on the source/drain region 105 is a thin film structure and has a level higher than that of the gate oxide layer 102 calculated from the surface 101a of the substrate 101 thus when the FIB milling initially performed on the silicon substrate 101 and the STI 110 confronts with the interface of the silicon substrate 101 and the silicide layer 109, it means that the FIB milling will confront with the interface of the interface of the silicon substrate 101 and gate oxide layer 102 immediately. Besides, because the silcide layer 109 has an electrical conductivity greater than that of the silicon substrate 101 and the STI 110, such that the secondary electron energy variation measured on the interface of the silicon substrate 101 and the silicide layer 109 is steeper than that measured on the interface of the silicon substrate 101 and STI 110. Therefore, in a preferred embodiment, the detector 207 used to determine the etching endpoint of the dry etching process 108 can measure a significant variation in secondary electron energy on the interface of the silicon substrate 101 and the silicide layer 109.

Alternatively, other method for determining the etching endpoint of the dry etching process 108 may be applied. In another embodiment of the present invention, the etching endpoint of the dry etching process 108 can be determined by measuring the second electron energy in associate with a grounding circuit 301.

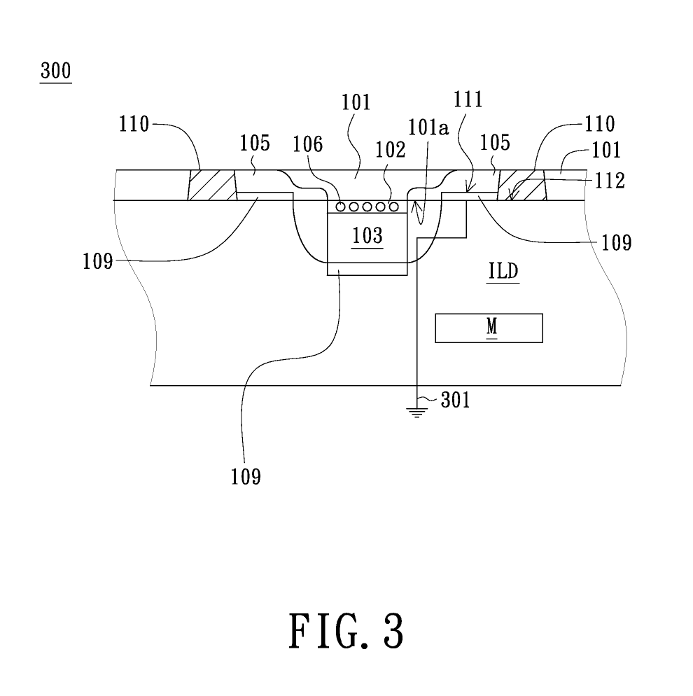

FIG. 3 illustrates a cross-sectional view of a transistor 300 under a pinhole inspection process in accordance with one embodiment of the present invention. In comparison with the transistor 100, a grounding circuit 301 is additionally provided to ground the silicide layer 109. Because the second electrons generated by the dry etching process 108 can be grounded via the grounding circuit 301 to trigger the second electron energy instantly increased while the dry etching process 108 confronts with the grounded silicide layer 109, such that this kind of second electron energy variation can be also used to determine the etching endpoint of the dry etching process 108. Of noted that, since the make and use of a grounding circuit arranged in a semiconductor device has been well known by the person skilled in the art, thus the grounding circuit 301 shown in FIG. 3 is just illustrative the detail structure thereof will not redundantly described.

It should be noted that, referring to FIG. 1C, while the etching endpoint is determined and the dry etching process 108 is stopped on the interface of the silicon substrate 101 and the silicide layer 109, there still remains a thin layer of silicon substrate 101 on the gate oxide layer 102. In other words, the dry etching process 108 is stopped before the ion beam milling confronts with the gate oxide layer 102, and the remaining silicon substrate 101 can protect the gate oxide layer 102 from being damaged by the ion beam milling. Therefore, the cross-sectional morphology or topography of the gate oxide layer 102 can also be protected from being deformed by the ion beam milling.

Afterward, the dry etching process is followed by a plane view or cross-sectional morphology or topography inspection. In some embodiments, the cross-sectional morphology or topography of the insulator layer is inspected by the TEM 204 of the FIB tool 201. Alternatively, in some other embodiments, a SEM or an optical microscope may be applied to inspect the plane view or cross-sectional morphology or topography of the insulator layer 102. By inspecting the cross-sectional morphology or topography of the gate oxide layer 102, the pinholes 106 which cause the transistor 100 defect can be discovered and studied by the engineers, thereby the cause of defect can be found and cured to prevent feature ones.

It should be appreciated that, the aforementioned pinhole inspection method is not only applicable to the backside inspection of a semiconductor device but also to the front side inspection. Besides, the aforementioned pinhole inspection method is also suitable for inspecting the transistor with a high k metal gate, wherein the target of the pinhole inspection is a bi-layer (or multiple-layer) structure at least consisting of an oxide layer and a high-k dielectric layer disposed under a metal gate.

In accordance with the aforementioned embodiments of the present invention, a method for inspecting pinholes formed in an insulator layer of a semiconductor device is provided, an etching process is firstly performed to remove the contiguous layer adjacent to the insulator layer under inspection; an etching endpoint is then determined by a second electron energy variation triggered by the dry etching process; after the etching process is stopped, the plane view and cross-sectional morphology or topography of the insulator is inspected. Since the dry etching process can be precisely stopped in accordance with the second electron energy variation before the insulator is damaged, such that the pinholes existing in the insulator layer can be well maintained without deformation and the “Failure analysis” can be performed more easily and efficiently. Therefore, the drawbacks and problems encountered from the prior art can be solved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A pinhole inspection method of an insulator layer, comprising:
conducting a dry etching process to remove a contiguous layer adjacent to the insulator layer;
determining an etching endpoint and then stopping the dry etching process in accordance with a second electron energy variation triggered by the dry etching process; and
inspecting a cross-sectional morphology or topography of the insulator layer.

2. The pinhole inspection method according to claim 1, wherein the dry etching process is a focus ion beam (FIB) milling process.

3. The pinhole inspection method according to claim 1, wherein a thin layer of the contiguous layer is remained after the dry etching process is carried out.

4. The pinhole inspection method according to claim 1, wherein the insulator layer is a silicon oxide layer.

5. The pinhole inspection method according to claim 4, wherein the contiguous layer is a silicon substrate for forming a semiconductor device.

6. The pinhole inspection method according to claim 5, further comprising a pre-thinning process to remove a portion of the silicon substrate prior to performing the dry etching process.

7. The pinhole inspection method according to claim 1, wherein the determination of the etching endpoint comprises steps of grounding the insulator layer, whereby the etching endpoint can be determined while the second electron energy is significantly increased.

8. The pinhole inspection method according to claim 1, wherein the determination of the etching endpoint comprises steps of imposing a voltage to the contiguous layer which is subjected to the dry etching process, whereby the etching endpoint is determined while the second electron energy steeply varies.

9. The pinhole inspection method according to claim 1, wherein the cross-sectional morphology or the topography of the insulator layer is inspected by utilizing an electron microscope or an optical microscope.

10. The pinhole inspection method according to claim 9, wherein the electron microscope is a transmission electron microscope (TEM), a scanning electron microscope (SEM) or a Focus ion beam (FIB) microscope.

11. A pinhole inspection method of a gate oxide layer, comprising:
conducting a dry etching process to remove a contiguous layer adjacent to the gate oxide layer;
determining an etching endpoint and then stopping the dry etching process in accordance with a second electron energy variation triggered by the dry etching process; and
inspecting a cross-sectional morphology or topography of the gate oxide layer.

12. The pinhole inspection method according to claim 11, wherein the dry etching process is an FIB milling process.

13. The pinhole inspection method according to claim 11, wherein a thin layer of the contiguous layer is remained after the dry etching process is carried out.

14. The pinhole inspection method according to claim 11, wherein the contiguous layer is a silicon substrate for forming a transistor.

15. The pinhole inspection method according to claim 14, wherein the transistor has a high-k metal gate.

16. The pinhole inspection method according to claim 14, further comprising a pre-thinning process to remove a portion of the silicon substrate prior to performing the dry etching process.

17. The pinhole inspection method according to claim 11, wherein the determination of the etching endpoint comprises steps of grounding the gate oxide layer, whereby the etching endpoint can be determined while the second electron energy is significantly increased.

18. The pinhole inspection method according to claim 11, wherein the determination of the etching endpoint comprises steps of imposing a voltage to the contiguous layer which is subjected to the dry etching process, whereby the etching endpoint can be determined while the second electron energy steeply varies.

19. The pinhole inspection method according to claim 11, wherein the cross-sectional morphology or the topography of the gate oxide layer is inspected by utilizing an electron microscope or an optical microscope.

20. The pinhole inspection method according to claim 19, wherein the electron microscope is a TEM, a SEM or a FIB microscope.
